(19) United States
(12) Patent Application Publication
(10) Pub. No.: US 2025/0133719 A1
(43) Pub. Date: Apr. 24, 2025

(54) MEMORY DEVICE HAVING HEXAGONAL MEMORY CELLS WITH PILLAR LATTICE

(71) Applicant: Micron Technology, Inc., Boise, ID (US)

(72) Inventors: Fatma Arzum Simsek-Ege, Boise, ID (US); Christopher K. Morzano, Boise, ID (US); Efe Sinan Ege, Boise, ID (US)

(21) Appl. No.: 18/777,365

(22) Filed: Jul. 18, 2024

Related U.S. Application Data
(60) Provisional application No. 63/544,709, filed on Oct. 18, 2023.

(51) Int. Cl. H10B 12/00

(52) U.S. Cl. CPC H10B 12/315; H10B 12/05; H10B 12/482

(57) ABSTRACT

A variety of applications can include a memory device having an array of memory cells, with each of the memory cells having a gate-all-around (GAA) transistor arranged as a hexagonal vertical channel transistor coupled to a capacitor. Access lines can be coupled to gates of the GAA transistors and digit lines can be coupled to pillar channels of the GAA transistors. A lattice can be included between the access lines and the digit lines, where the lattice has dielectric regions between and contacting non-dielectric regions. Each non-dielectric region can be positioned on and contacting a digit line and can contain digit contact junctions to the pillar channels of a set of the GAA transistors extending from the non-dielectric region. Additional devices and methods are disclosed.

### PRIORITY APPLICATION

This application claims the benefit of priority to U.S. Provisional Application Ser. No. 63/544,709, filed Oct. 18, 2023, which is incorporated herein by reference in its entirety.

### FIELD OF THE DISCLOSURE

Embodiments of the disclosure relate generally to integrated circuits and, more specifically, to memory devices and formation thereof.

### BACKGROUND

Memory devices are typically provided as internal, semiconductor, integrated circuits (ICs) in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the design and fabrication of components of the electronic devices such as, but not limited to, memory devices in an IC for the electronic devices.

### BRIEF DESCRIPTION OF THE DRAWINGS

The drawings, which are not necessarily drawn to scale, illustrate

generally, by way of example, but not by way of limitation, various embodiments discussed in the present document.

FIG. 1 illustrates a representation of an example structure having an array of memory cells arranged as hexagonal memory cells, in accordance with various embodiments.

FIG. 2 illustrates a top view of an example representation of an open digit line architecture in which multiple instances of the structure of FIG. 1 can be implemented, in accordance with various embodiments.

FIG. 3 illustrates a bottom portion of the structure of FIG. 1, in accordance with various embodiments.

FIG. 4 is a top view of portions of the structure of FIG. 1 illustrating pillar channels supported by a lattice, in accordance with various embodiments.

FIGS. 5 and 6 provides a comparison of hexagonal cells and square cells, in accordance with various embodiments.

FIGS. 7-28 illustrate an example process flow of forming a memory device having the arrangement of memory cells of the structure of FIG. 1, in accordance with various embodiments.

FIG. 29 illustrates an example architecture in which the structure of FIG. 28 or similar structure can be located, in accordance with various embodiments.

FIG. 30 is a flow diagram of features of an example method of forming a memory device, in accordance with various embodiments.

FIG. 31 is a flow diagram of features of an example method of forming a memory device, in accordance with various embodiments.

FIG. 32 is a schematic of electrical arrangement of components of an example dynamic random-access memory device that can include an architecture having hexagonal memory cells with gate-all-around transistors, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above and can be in a direction from the horizontal or to the horizontal. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In various embodiments, a memory device can be structured with an array of memory cells arranged as hexagonal cells, where each of the memory cells has a gate-all-around (GAA) transistor coupled to a capacitor. A hexagonal memory cell is a memory cell that is surrounded by six other memory cells such that these other memory cells are at vertices of a hexagonal structure formed by connecting the centers of adjacent memory cells of the other memory cells. A GAA transistor is a transistor structured with the gate of the transistor coupled to the channel structure of the transistor on all sides of the channel structure. The GAA transistor can be structured as a thin film transistor (TFT). The GAA transistor can be structured in a pillar arrangement containing active areas (source and drain) and the channel structure about which the gate is structured around. The gate can be separated from the channel structure by a gate dielectric. The pillar structure of the GAA transistor can be structured as a semiconductor nanowire.

Nanowires are nanostructures having a diameter on the order of nanometers. A GAA nanowire transistor as an access device to a capacitor in memory cells of a DRAM can provide enhanced I_{ON} capability and flexible adjustment of transistor threshold voltage (V_{T}). I_{ON} is the on-state current of the transistor, and I_{OFF} is the off-state current of the transistor. The ratio, I_{ON}/I_{OFF}, is a figure of merit for high performance and low leakage power for the transistor. High performance is associated with more I_{ON} and low leakage power is associated with less I_{OFF}.

The memory device, having one or more arrays of hexagonal memory cells of GAA transistors, can be implemented with control logic and sensing circuitry in a number of different architectures. The control logic and sensing circuitry can be located in a periphery region adjacent to an array of hexagonal memory cells on a wafer that is an IC chip. Another compatible architecture includes the control logic and sensing circuitry located under the one or more memory arrays in a circuit under array (CuA) architecture. The control logic and sensing circuitry can be arranged for sensing the programmed data states of memory cells of one or more memory arrays of the memory device, and can enhance reduction of die size or increase utilization of space in a die or combination of dies. CuA refers generally to circuitry located in a memory die under a memory array of the memory die. With the control logic and sensing circuitry fabricated under the memory array using semiconductor processing that can include complementary metal oxide semiconductor (CMOS) processing technology, CuA can also be referred to as CMOS under array. Another compatible architecture can include control logic and sensing circuitry located above the memory arrays in a circuit over array (CoA) architecture. The control logic and sensing circuitry can be arranged for sensing the programmed data states of memory cells of one or more memory arrays of the memory device, and can enhance reduction of die size or increase utilization of space in a die or combination of dies. CoA refers generally to circuitry located in a memory die over one or more memory arrays of the memory die. With the control logic and sensing circuitry fabricated over the one or more memory arrays using semiconductor processing that can include CMOS, CoA can also be referred to as CMOS over array. The CuA architecture and the CoA architecture can be implemented by a wafer-to-wafer architecture, where the control logic and sensing circuitry is formed on one wafer and the one or more memory arrays are formed on another wafer, with the two wafers combined. Wafer-to-wafer interconnect architectures can include a wafer-on-wafer architecture. Wafer-to-wafer bonding of back-to-back wafers with a CoA architecture can provide for the movement of a capacitor module for data storage in a DRAM to the bottom of the stack of wafers. This arrangement can reduce interconnect congestion between the stacked wafers.

The memory device can include a set of access lines (WLs), where each WL of the set of WLs can be coupled to gates of a first set of multiple GAA transistors of the memory cells of a memory array. Each WL can be formed with the formation of corresponding gates of GAA transistors in a replacement gate process, which can provide enhanced gate control. The memory device can include a set of digit lines (BLs), where each BL of the set of BLs can be coupled to a second set of multiple GAA transistors of the memory cells. The WLs can be separated vertically from the BLs. A lattice can be structured between the BLs and the WLs, where the lattice is a structure added to the process flow in the fabrication of the memory cells to ensure the structural stability of the cell by preventing toppling of the vertical structure of the cell. Such a lattice can reduce pillar etch aspect ratio in fabrication by a significant amount, for example in the range of 40%. In addition, each BL can be at least partially wrapped around an active area of the GAA transistors to which the given BL is coupled. With the BL at least partially wrapped around the active area, a reduction in resistance-capacitance (RC) parameter can be attained.

The memory device can have a 4F² memory array configuration, where a memory cell in a row of memory cells coupled to a BL can share the BL with an adjacent memory cell in a directly adjacent row of memory cells. Memory cell sizes are measured using an nF² formula where ‘n’ is a constant derived from the cell design and ‘F’ is the feature size of the process technology. A unit repeating cell of a 4F² cell is a parallelogram having sides of equal length of 2F. For the same feature size, as the cell size becomes smaller, memory capacity increases. In a 4F² memory cell configuration, the WL pitch and the BL pitch equal 2F.

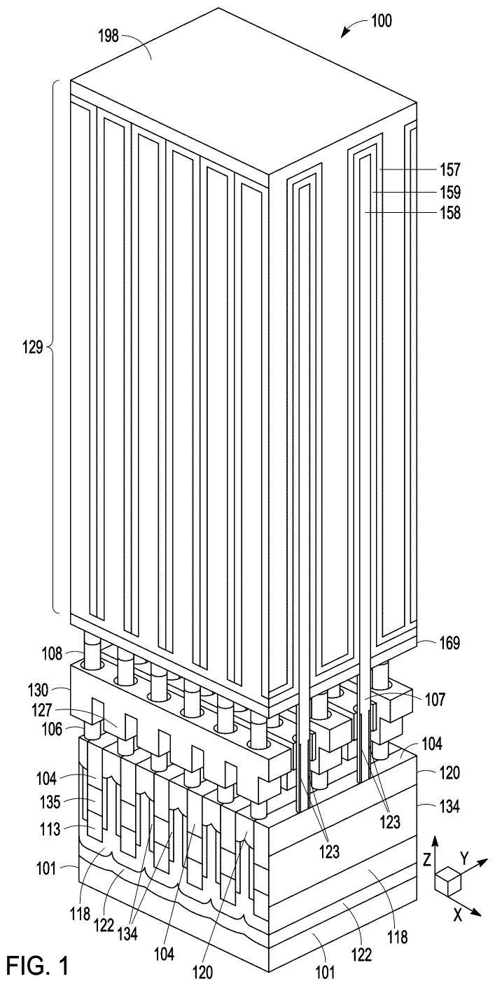

FIG. 1 illustrates a structure 100 having an arrangement of memory cells, where each memory cell has an access transistor and a capacitor, where the access transistor is a GAA transistor having a pillar channel supported by a lattice. Various dielectric regions are not shown to focus on active components of structure 100. One of similar multiple features in FIG. 1 and in subsequent figures may be labelled without labeling all similar features, for ease of presentation. The memory cells are arranged on a wafer 101, which can be referred to as an array wafer 101, since the memory cells are structured at a level above wafer 101 during fabrication. A bonding dielectric 122 is positioned on array wafer 101, where the bonding dielectric 122 was structured in fabrication to bond to array wafer 101 that can be used as a carrier during placement of structure 100 in a memory device. A dielectric 118 is located on bonding dielectric 122. BLs are positioned above bonding dielectric 122 within dielectric 118, where a BL has a central BL region 135 contacting side BL regions 134 with central BL region 135 on and contacting a dielectric 113. In this example, central BL region 135 and side BL regions 134 have an H-shape in the cross-sectional view of a BL.

Structure 100 includes pillar channels 107 supported by a lattice, which is a regular arrangement of material over an area or over volume. The lattice of structure 100 has dielectric regions 120 between and contacting non-dielectric regions 104, where each non-dielectric region 104 is on and contacting a BL. Non-dielectric region 104 is on a central BL region 135, where portions of non-dielectric region 104 contact top portions (relative to bonding dielectric 122 and array wafer 101) of side BL regions 134. Non-dielectric region 104 contains digit contact junctions (BL contact junctions) to pillar channels 107 of a set of the GAA transistors, where pillar channels extend from non-dielectric region 104 and extend above about a level at the top of dielectric region 120.

Pillar channels 107 can be vertical semiconductor pillars. Pillar channels 107 can be realized as nanowires. Each pillar channel 107 includes a channel between two source/drain regions. For each pillar channel 107, a gate dielectric 123 can be positioned around the channel provided by pillar channel 107. A gate 127 is positioned around each gate dielectric 123 and pillar channel 107 with a WL 130 contacting gate 127. Gate 127 and WL 130 can be structured in a format with WL 130 integrated with multiple gates 127, as shown in the x-direction of FIG. 1. The two source/drain regions of each pillar channel 107 are active areas. Each active area can include a contact junction. For each pillar channel 107, the channel is coupled to a capacitor 129 by active area 108 having a cell contact junction and is coupled to a BL, having a central BL region 135 contacting side BL regions 134, by an active area 106 having a digit contact junction (a digit contact can be referred to as a bit contact or bitcon). Each BL, having a central BL region 135 contacting side BL regions 134, can be at least partially wrapped on a sidewall of active area 106. Bitcon junction areas can be configured as shields to reduce the capacitance between the BLs. Alternatively, digit shields can be structured between adjacent BLs.

A dielectric 169 is located above WLs 130 and gates 127. Dielectric 169 results from the processing of structure 100 and provides electric isolation to conductive components in structure 100. Above dielectric 169 are a set of capacitors 129. Each capacitor 129 includes a capacitor dielectric 159 between two electrodes 157 and 158. Electrode 158 can be referred to as a bottom electrode that is coupled to active area 108 of pillar channel 107, while electrode 157 is a top electrode that can be coupled to a reference node. Capacitor dielectric 159 can be, but is not limited to, a high-k dielectric. A high-k dielectric is a dielectric having a dielectric constant greater than the dielectric constant of silicon dioxide. Structure 100 can include a dielectric region 198 or connecting wafer on the set of capacitors 129.

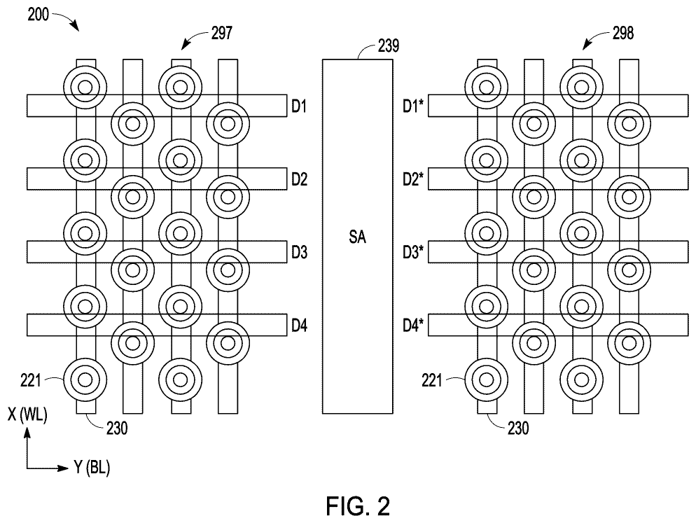

FIG. 2 illustrates a top view of an example representation 200 of an open BL architecture in which multiple instances of structure 100 of FIG. 1 can be implemented, where a memory cell 221 in a row of memory cells coupled to a BL can share the BL with an adjacent memory cell 221 in a directly adjacent row of memory cells. In an open BL architecture, the BLs are divided into multiple segments and differential sense amplifiers (SAs) can be placed between BL segments. BLs can be taken to a SA in pairs, where the BLs are taken from different array patches. An array patch, which can also be referred as a mat, is a structure for a sub-array of memory cells of a larger memory array of a memory device such as the example structure 100 of FIG. 1. An open BL architecture can be referred to as an open SA architecture.

The open BL architecture of representation 200 can be structured for a 4F² architecture and includes a SA 239. BLs D1, D2, D3, and D4 are in an array patch 297 coupled to SA 239. Array patch 297 includes multiple WLs 230, with each WL 230 not shared with any adjacent bits, that is, for a linear arrangement of memory cells, a memory cell coupled to a given WL 230 does not share the given WL 230 with a memory cell of a directly adjacent linear arrangement of memory cells. For example, array patch 297 can include each WL 230 having a set of multiple memory cells 221, where directly adjacent memory cells 221 to a given WL 230 are not addressed by the given WL 230. Each WL 230 can be integrated with a gate of GAA transistor of each memory cell 121 of the set of multiple memory cells 221 that the given WL 230 can address. BLs D1*, D2*, D3*, and D4* are in array patch 298, which includes multiple WLs 230, with each WL 230 not shared with any adjacent bits. For example, array patch 298 can include each WL 230 having a set of multiple memory cells 221, where adjacent memory cells 221 to a given WL 230 are not addressed by the given WL 230. Each WL 230 can be integrated with a gate of GAA transistor of each memory cell 121 of the set of multiple memory cells 221 that the given WL 230 can address.

BLs D1, D2, D3, and D4 from array patch 297 can be paired with BLs D1*, D2*, D3*, and D4* from array patch 298, respectively, where array patch 297 is different from array patch 298. The BL pairs can be coupled to SA 239. Array patch 297 and Array patch 298 can be formed in individual subtractive processes, with each array patch having a structure 100 of FIG. 1 or similar structure. A substrative process includes removing material from a solid block of starting material.

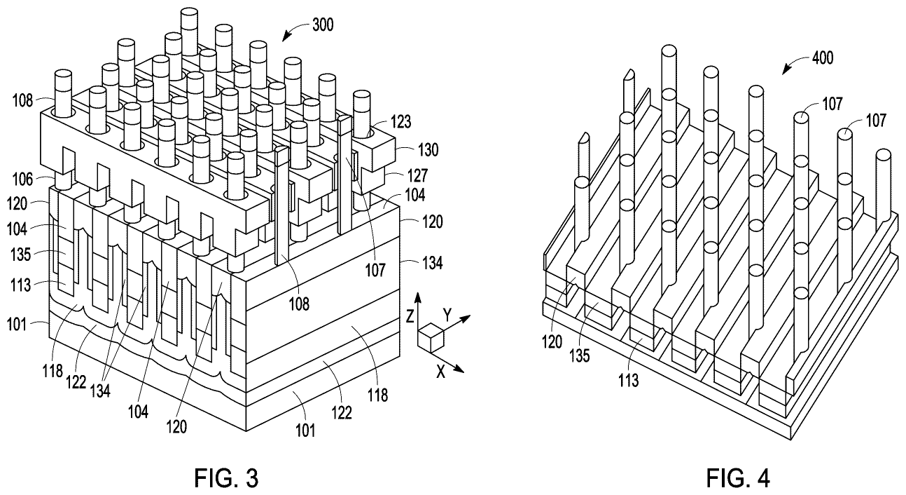

FIG. 3 illustrates a representation 300 of a bottom portion of structure 100 of FIG. 1. Representation 300 shows the lattice having dielectric regions 120 situated between WLs 130 and BLs, each BL having a central BL region 135 contacting side BL regions 134, and illustrates that the lattice can provide support for pillar channels 107 to prevent toppling in fabrication of structure 100. FIG. 4 is a top view of portions of the structure 400 of FIG. 1 further illustrating pillar channels 107 supported by dielectric regions 120 of the lattice of structure 100.

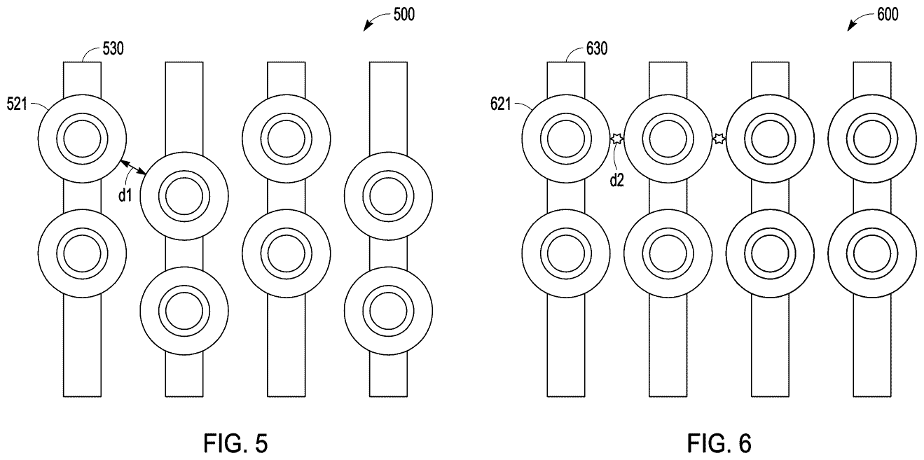

FIGS. 5 and 6 provide a comparison of GAA hexagonal cells of a structure 500 and GAA square cells of a structure 600 that can be implemented in a 4F² architecture. Hexagonal GAA cell 521 coupled to a given WL 530 has a margin d1 to the GAA cell 521 of a directly adjacent WL 530. Hexagonal GAA cell 621 coupled to a given WL 630 has a margin d2 to the GAA cell 621 of a directly adjacent WL 630, where d2<d1. Hexagonal cells 521 of structure 500 have a better margin compared to the margin of square cells 621 of structure 600. The staggered arrangement of GAA cells in hexagonal form relaxes the WL pitch compared to the arrangement of GAA cells in square form. WL pitch is a minimum distance between centers of adjacent WLs in a set of WLs. A margin between two cells is a minimum distance between the two cells, which for cells with GAA access transistors, can be the distance between the outer boundary of the all-around gates of the GAA access transistors.

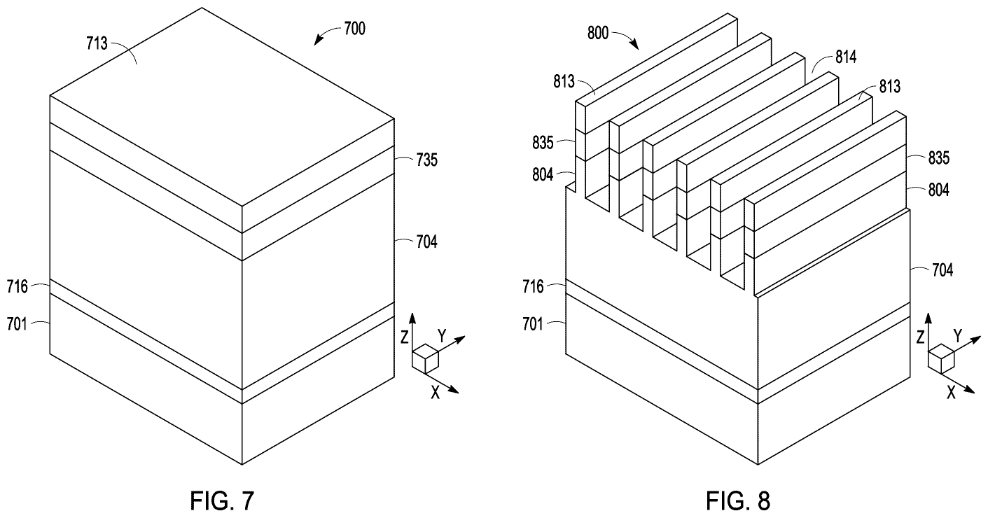

FIGS. 7-29 illustrate an embodiment of an example process flow of forming a memory device having an arrangement similar to the arrangement of memory cells of structure 100 of FIG. 1. The memory cells can be arranged with a 4F² architecture. For the processes discussed herein, the selection of processing materials can depend on the materials selected to form various components of and contacts to components of the memory device. The processing materials can be selected to allow removal of one or more materials, while retaining one or more other materials. In addition, deposition techniques can be used that are typical for the material being formed, the dimensions of the material being formed, and the architecture in which the material is being formed.

FIG. 7 shows a structure 700 after a block of material has been formed on a substrate 701. The block can include semiconductor material. For example, the block can be formed with a layer 716 of silicon germanium (SiGe) on substrate 701, where substrate 701 can be a silicon substrate. The SiGe can be 15% SiGe that can be formed by an appropriate deposition process. Materials other than SiGe can be used. The thickness of the SiGe from substrate 701 can be, but is not limited to, a range between approximately 10 to 20 nanometers. Formation of the block of material can include a layer 704 of epitaxial Si formed on the SiGe. Materials other than epitaxial Si can be used. The thickness of the epitaxial Si on the SiGe can be, but is not limited to, a range between approximately 150 nm and 300 nm, for example at 200 nm. Material for BLs 735 has been formed on layer 704. Material for BLs 735 can be a metal or other appropriate conductive material for a BL. A hard mask 713 has been formed on material for BLs 735. A hard mask is a material that can be used as a etch mask in an etch process, where the material is different from a polymer or other relatively soft material such as relatively soft resist materials. A hard mask is typically a high-density material used in the etch process to protect certain areas of a structure being processed from the etching chemicals being used in the etch process. Material for BLs 735 and hard mask 713 can be formed by a deposition process suitable for these regions. For example, material for BLs 735 can be formed by physical vapor deposition (PVD), chemical vapor deposition (CVD), or atomic layer deposition (ALD).

FIG. 8 shows a structure 800 after processing structure 700 of FIG. 7. Material for BLs 735, hard mask 713, and a top portion of layer 704 have been patterned forming BL strips 835, hard mask strips 813, and non-dielectric strips 804. The patterning can be attained by removing selected portions of hard mask 713 on material for BLs 735 on layer 704 through a significant portion of layer 704. The removal can be performed by etching down through approximately 30% of layer 704. The etching procedure can result in trenches 814 between vertical regions of a combination of hard mask strip 813 on BL strip 835 on a non-dielectric strip 804. Trenches 814 provide regions where a lattice for pillar channel will be placed for structural stability of the integrated scheme of structure 100 of FIG. 1.

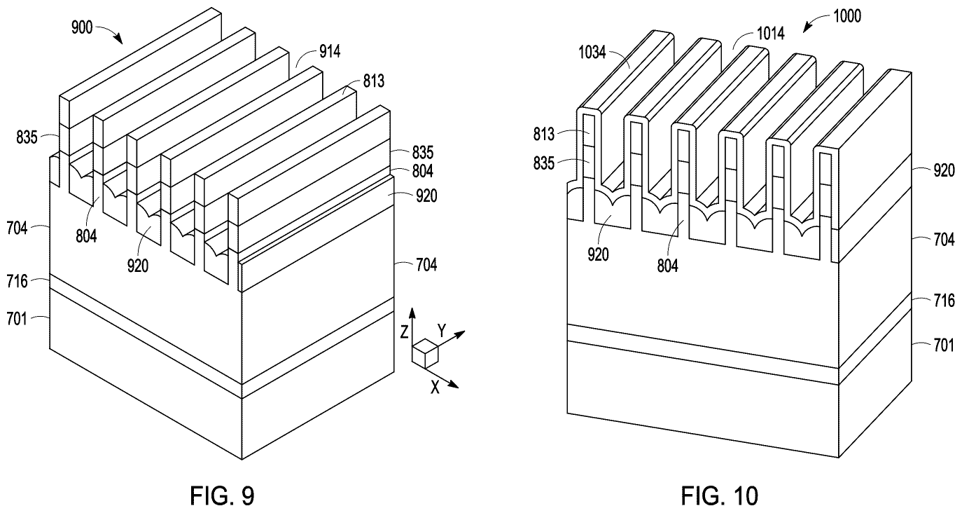

FIG. 9 shows a structure 900 after processing structure 800 of FIG. 8. A lattice dielectric 920 has been formed in trenches 814 of structure 800 and recessed, leaving smaller trenches 914. Lattice dielectric 920 can be formed by an appropriate deposition procedure for the material of lattice dielectric 920. Lattice dielectric 920 can include a nitric oxide (NO_{X}), a Si-rich nitride, an aluminum oxide (AlO_{X}), or combinations of dielectrics. At this juncture of the process flow, implants to BL contact junctions in non-dielectric strips 804 can be made. Alternatively, implants to BL contact junctions for non-dielectric strips 804 can be made to layer 704 prior to forming material for BLs 735 on layer 704.

FIG. 10 shows a structure 1000 after processing structure 900 of FIG. 9. Additional material for BLs 1034 has been formed on the surfaces of structure 900, covering lattice dielectrics 920, hard mask strips 813, and sides of BL strips 835. Trenches 914 have been reduced to trenches 1014. Additional material for BLs 1034 can be a metal, combinations of metals, or other appropriately conductive material. Additional material for BLs 1034 can be formed to provide a sidewall wrap for active areas of pillar channels to be formed. Additional material for BLs 1034 can be formed by a deposition process suitable for this additional material. For example, additional material for BLs 1034 can be ALD metals or CVD metals. Additional material for BLs 1034 can include complementary alloys to the material of BL strips 835 to lower the resistance of BLs formed by the combination of BL strips 835 and additional material for BLs 1034. The additional material for BLs 1034 can include molybdenum (Mo), cobalt (Co), ruthenium (Ru), titanium nitride (TiN), tantalum (Ta), other metallic material for the architecture of the BLs being formed, or combinations of metallic materials.

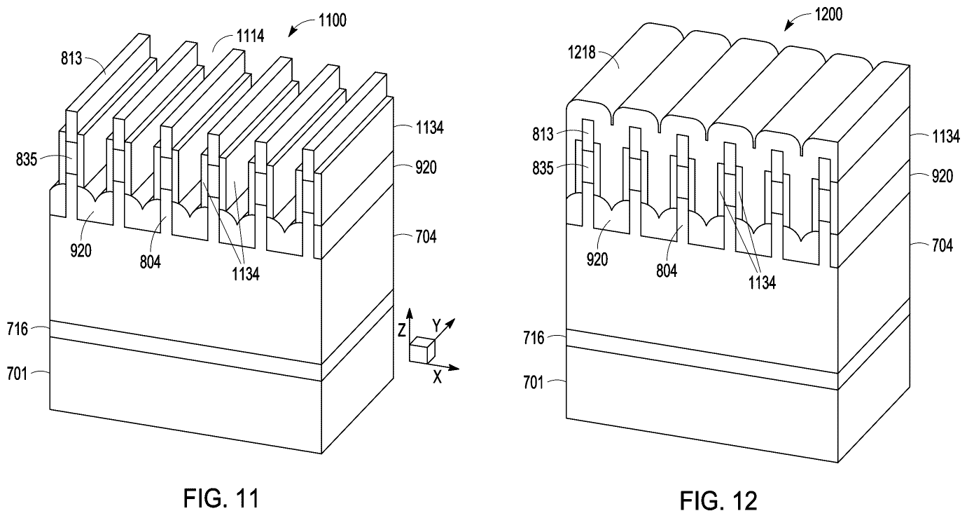

FIG. 11 shows a structure 1100 after processing structure 1000 of FIG. 10. Portions of additional material for BLs 1034 have been removed forming additional BL strips 1134 and providing a trench 1114 down to a top level of lattice dielectric 920. Hard mask strips 813 have been exposed in this processing. The removal of the portions of additional material for BLs 1034 can be performed as an etch operation, forming H-shape BLs having BL strips 835 as central BL regions and additional BL strips 1134 as side BL regions of the H structures.

FIG. 12 shows a structure 1200 after processing structure 1100 of FIG. 11. A dielectric 1218 has been formed on the surfaces of structure 1100 covering hard mask strips 813 and sides of additional BL strips 1134. Trenches 1114 have been filled with dielectric 1218. Dielectric 1218 can be deposited by a deposition appropriate for the material of dielectric 1218. Dielectric 1218 can be, but is not limited to, an oxide. Dielectric 1218 can be a low-k dielectric. A low-k dielectric is a dielectric having a dielectric constant less than the dielectric constant of silicon dioxide.

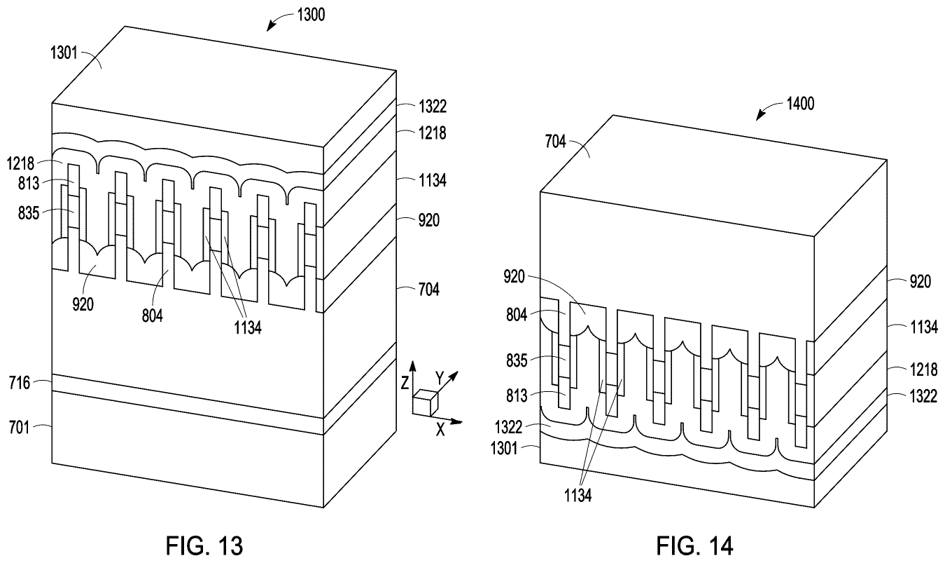

FIG. 13 shows a structure 1300 after processing structure 1200 of FIG. 12. A bonding dielectric 1322 has been formed on dielectric 1218 and a carrier wafer 1301 has been bonded to bonding dielectric 1322. Bonding dielectric 1322 can be buffed, subjected to a (chemical mechanical polishing) CMP process, and cleaned prior to bonding to carrier wafer 1301. Formation of bonding dielectric 1322 can be conducted using a deposition process appropriate for the material selected for bonding dielectric 1322. Material for bonding dielectric 1322 can be, but is not limited to, tetraethoxysilane (TEOS), silicon carbon nitride (SiCN) BLOK (barrier low k) layer, material for high aspect ratio process (HARP), or combinations of similar materials.

FIG. 14 shows a structure 1400 after processing structure 1300 of FIG. 13. Structure 1300 has been flipped and substrate 701 and layer 716 have been thinned down from the backside, stopping at the interface of layer 716 to layer 704. For a silicon-on-insulator case for layers 704, 716, and substrate 701, an oxide-buried oxide (Box) interface of the SOI can be used as the as back side etch stop.

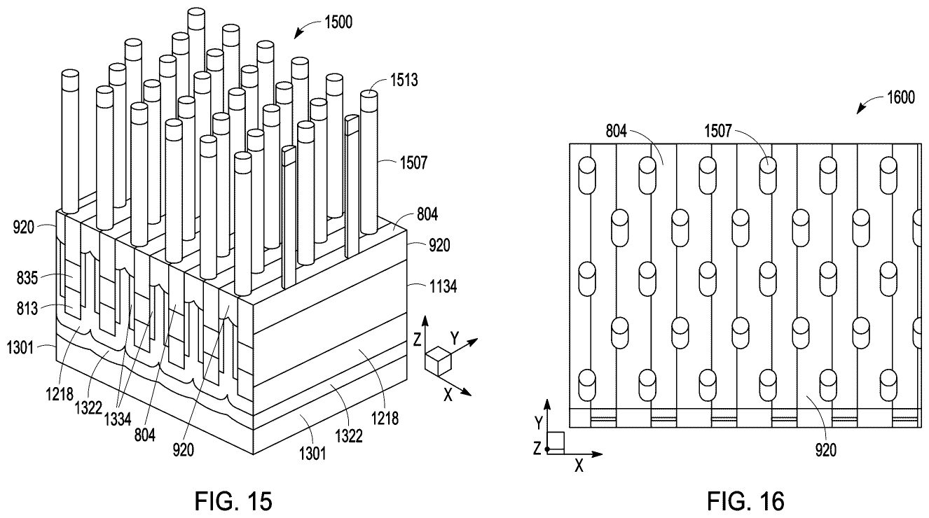

FIG. 15 shows a structure 1500 after processing structure 1400 of FIG. 14. Layer 704 and portions of non-dielectric strips 804 have been selectively etched to form pillar channels 1507 connected to non-dielectric strips 804, using a hard mask from which dielectric 1513 remains on top of pillar channels 1507. The pillar etch has stopped on lattice dielectric 920. At this portion of the process flow, an approximate 40% reduction of aspect ratio has been provided and structure integrity has been achieved by lattice integration. Photolithography can be used in the patterning and forming of pillar channels 1507 using deep ultraviolet radiation (DUV) or extreme ultraviolet radiation (EUV).

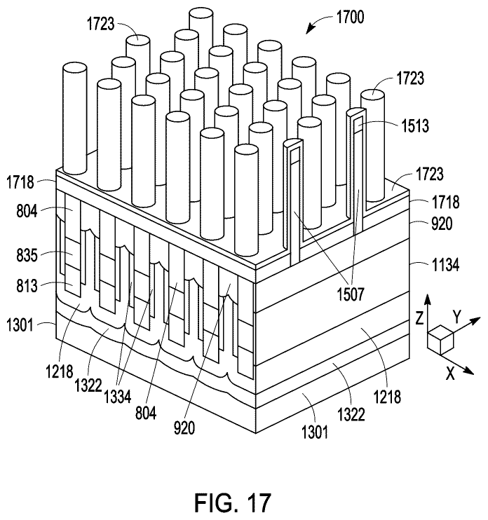

FIG. 16 shows a representation 1600 of a top view of structure 1500. Lattice dielectric 920 fills the region between non-dielectric strips 804 and at least partially around pillar channels 1507. Representation 1600 can have an aspect ratio of approximately 12.

FIG. 17 shows a structure 1700 after processing structure 1500 of FIG. 16. Dielectric material 1718 has been formed on the exposed surfaces of structure 1500. Dielectric material 1723 has been formed dielectric material 1718. Dielectric material 1723 covers the exposed portions of pillar channels 1507 and will provide a gate dielectric for GAA transistors being formed about pillar channels 1507. Dielectric material 1718 can be, but is not limited to, an oxide. Dielectric material 1723 can be, but is not limited to, a gate oxide material. Dielectric material 1723 can be formed by a deposition procedure that is suitable for the selected material for dielectric material 1723. Alternatively, dielectric material 1723 can be formed by in-situ steam generation (ISSG), where an ISSG procedure includes generation of steam in close proximity to a wafer surface, providing a wet oxidation.

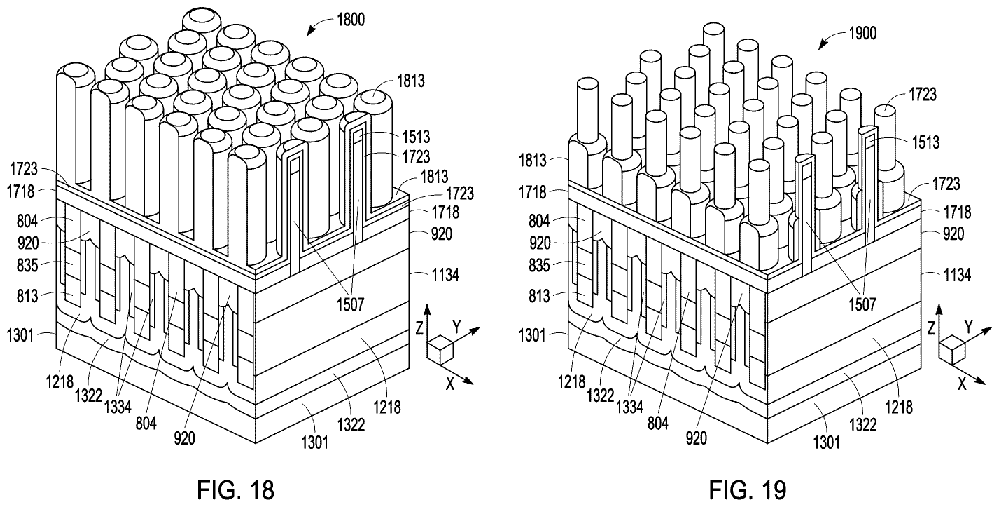

FIG. 18 shows a structure 1800 after processing structure 1700 of FIG. 17. A liner 1813 has been formed on the exposed surfaces of structure 1700. Formation of liner 1813 can be conducted using a deposition procedure appropriate for the material of liner 1813. Liner 1813 can be, but is not limited to, a nitride liner. Liner 1813 has been formed as a sacrificial liner in the process flow.

FIG. 19 shows a structure 1900 after processing structure 1800 of FIG. 18. Liner 1813 has been selectively etched back exposing portions of dielectric material 1723. A dry etch can be used. The dry etch can be selective to dielectric material 1723 being a high-k dielectric or a gate oxide.

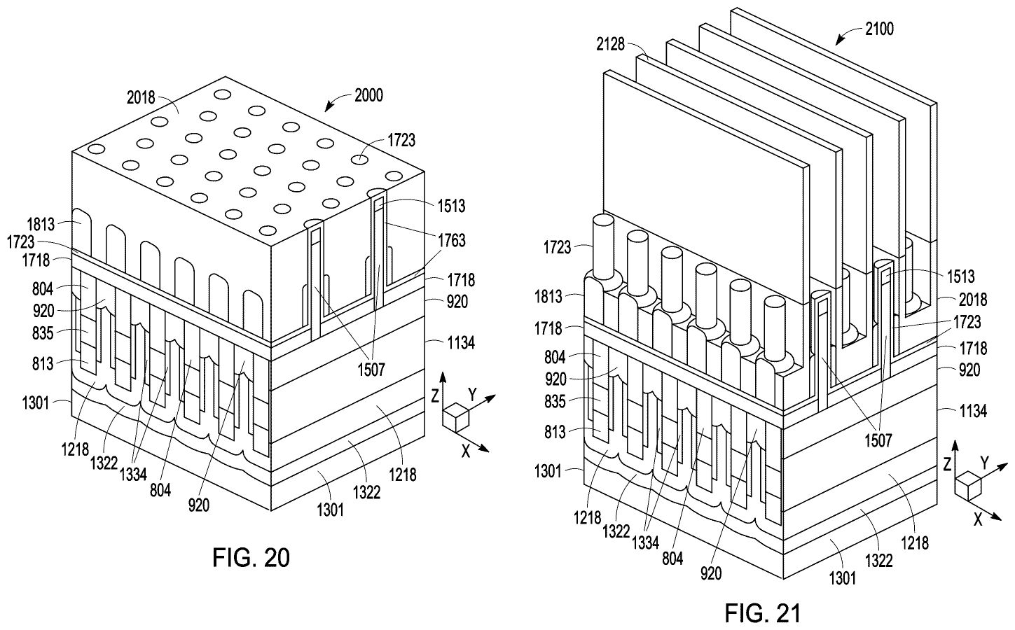

FIG. 20 shows a structure 2000 after processing structure 1900 of FIG. 19. An isolation dielectric 2018 has been formed on the exposed surfaces of structure 1900. Isolation dielectric 2018 can be subjected to a CMP procedure that exposes tops of dielectric material 1723. The fill of the isolation dielectric 2018 can include an oxide, a spin-on-dielectric (SOD) material, a low-k polymer, or other dielectric material.

FIG. 21 shows a structure 2100 after processing structure 2000 of FIG. 20. A photolithographic procedure has been conducted for preparing WLs, providing a carbon-based hard mask 2128 on selected sections of isolation dielectric 2018. Carbon-based hard mask 2128 was generated as an underlayer placed under photoresist in the photolithographic procedure. A dry etch can be used to form the pattern of carbon-based hard mask 2128 that separates rows of dielectric material 1723.

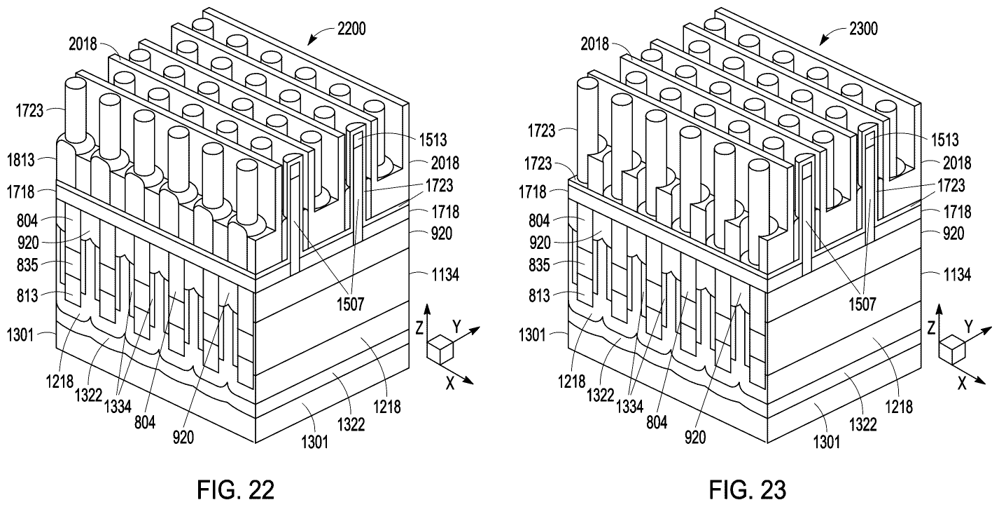

FIG. 22 shows a structure 2200 after processing structure 2100 of FIG. 21. Carbon-based hard mask 2128 has been removed, providing a top level of structure 2200 at the tops of dielectric material 1723. The removal process can include an oxide etch that stops on liner 1813 between columns of dielectric material 1723.

FIG. 23 shows a structure 2300 after processing structure 2200 of FIG. 22. Liners 1813 have been selectively removed, where liners 1813 were formed as a sacrificial liners. With liner 1813 being a sacrificial nitride, the removal procedure can include removing liner 1813 using a wet etch selective to maintain dielectric material 1723 and lower portions of dielectric 2018. With liners 1813 being nitrides, removal of liners 1813 can be selective to maintain an oxide or other dielectric of dielectric material 1723. For example, the selective etchant can include a hot phosphide. The removal procedure has maintained regions of dielectric 2018 positioned to provide insolation between sets of linearly arranged pillars covered by dielectric material 1723.

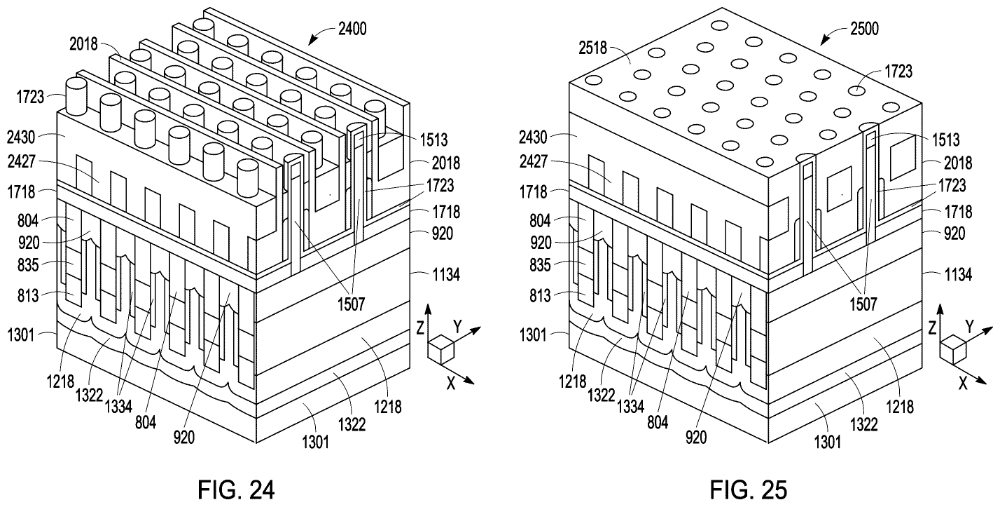

FIG. 24 shows a structure 2400 after processing structure 2300 of FIG. 23. Conductive material 2427 has been formed for gates, which can be referred to as gates 2427, and conductive material 2430 has been formed for WLs, which can be referred to as WLs 2430. Conductive material 2427 can be formed as metal deposited to form gates of GAA transistors and conductive material 2430 can be formed as metal deposited to form the WLs. The formed conductive material 2430 has been recessed back to form the shape of conductive material 2430 as shown in FIG. 24.

FIG. 25 shows a structure 2500 after processing structure 2400 of FIG. 24. Dielectric 2518 has been formed as a partial fill, followed by performing a CMP procedure exposing tops of dielectric material 1723. Dielectric 2518 can be, but is not limited to, an oxide. The junctions of the cell contacts of pillar channels 1507 can be implanted for coupling to capacitors. The implants can be n+implants.

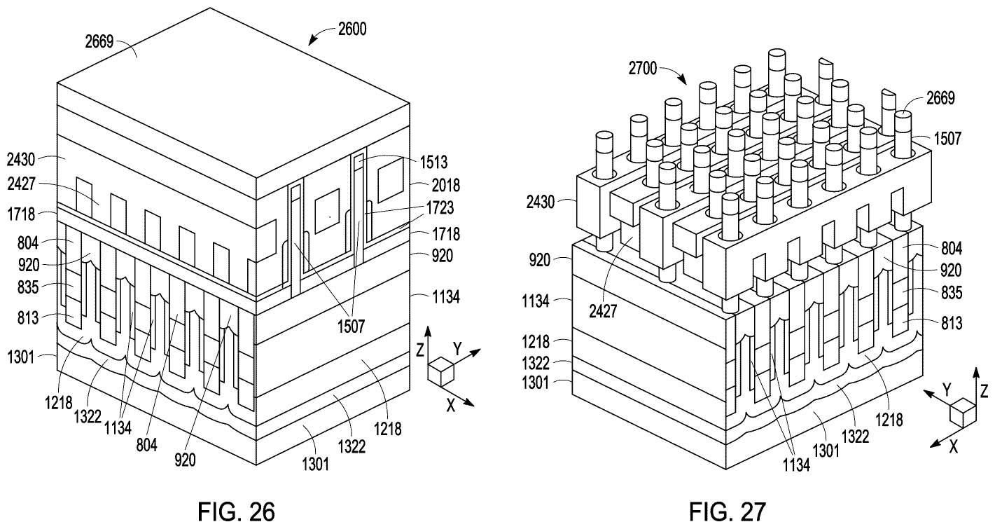

FIG. 26 shows a structure 2600 after processing structure 2500 of FIG. 25. An etch stop 2669 has been formed. Etch stop 2669 can be formed by a deposition procedure appropriate for the material used for the etch stop 2669. Etch stop 2669 can be a nitride etch stop. Etch stop 2669 can be, but is not limited to, SiN having a thickness (depth top surface of etch stop 2639) of approximately 100 nm. Etch stop 2669 has been provided for formation of a capacitor module.

FIG. 27 shows a representation 2700 of structure 2600 of FIG. 26 with various dielectric components not shown. Representation 2700 illustrates the relationship of pillar channels 1507, gates 2427 for GAA transistors, WLs 2430, and H-shaped BLs formed by BL strips 835 and additional BL strips 1134 with respect to lattice dielectric 920 between and contacting non-dielectric strips 804.

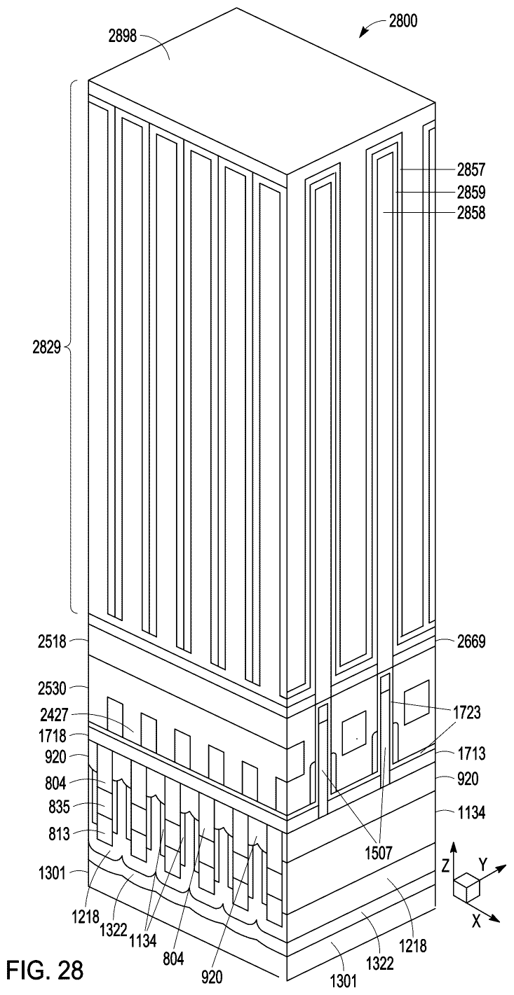

FIG. 28 shows a structure 2800 after processing structure 2600 of FIG. 26. Integration of a capacitor module has been made. A set of capacitors 2829 has been formed on etch stop 2669. A cover layer 2898 has been formed on the top of the set of capacitors 2829. In forming the capacitors, bottom electrodes 2858 have been formed coupled to pillar channels 1507. Top electrodes 2857 have been formed, separated from bottom electrodes 2858 by capacitor dielectrics 2859. Capacitor dielectrics 2859 can be formed, but are not limited to, high-k dielectrics. The capacitor process can be implemented using the same mask-set that was used to pattern the active areas. The capacitor module can be aligned on the junction of the cell contact-active area-channel arrangement provided by pillar channels 1507. Structure 2800 provides an array structure that is ready to be processed with control and sensing circuitry of a memory device such as a DRAM device. Cover layer 2898 can be a wafer used to mount structure 2800 for coupling to the control and sensing circuitry.

The process flow of FIGS. 7-28 provides a number of enhancements to memory devices such as DRAM devices. WLs can be formed as replacement gates of GAA transistors, which can provide enhanced gate control. GAA hexagonal memory cells, as taught herein, can provide for capacitor structures that allows the use of redistribution layers (RDLs) to be skipped. A typical DRAM uses RDL interconnect to rotate cell contact to a hexagonal form for a capacitor to land on. A capacitor is preferred in hexagonal form, because it has the highest surface area (hence the storage capacity) when it is hexagonal. Having a hexagonal active area, removes the need for patterning a hexagonal RDL module.

Various deposition techniques for components in the process flows discussed herein can be used that are typical for the material being formed, the dimensions of the material being formed, and the architecture in which the material is being formed in the fabrication of the memory device. Material and structures can be formed by a suitable process such as, but not limited to, a deposition process, where the deposition process can include, but is not limited to, PVD, CVD, ALD, or other deposition processes. Other processes can be used. Selective etching can be used to remove selected regions in the processing discussed with respect to the process flows. Selective etching is a process in which one or more materials are removed from a structure, while one or more other materials remain in the structure with little or no removal. Selective etching can depend on the material to be etched, the material not to be etched, the etchant employed, and the method for etching. Types of etching include wet etching and dry etching, where each of these two basic methods include a number of different etching procedures. In addition, conventional masking techniques, providing protective regions in the processing, can be used in removal of selected regions in forming the components of the memory device.

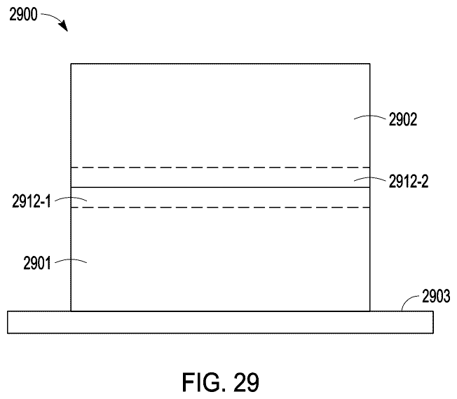

FIG. 29 illustrates an embodiment of an example architecture 2900 in which structure 2800 of FIG. 28 or similar structure can be located. Architecture 2900 is structured as a wafer-to-wafer interconnect architecture, which includes a control wafer 2902 having a bonding region 2912-2 attached to an array wafer 2901 having a bonding region 2912-1. The combination of control wafer 2902 attached to array wafer 2901 can be mounted on a carrier wafer 2903 or other appropriate platform. Control wafer 2902 can be attached to array wafer 2901 by conducting a bonding of bonding region 2912-1 to bonding region 2912-2. The bonding process can be conducted through fusion bonding. Array wafer 2901 can include one or more of structures 2800 or similar structures having one or more arrays of memory cells. Control wafer 2902 can include control and sensing circuitry for operation of arrays of memory cells of the one or more structures 2800 of array wafer 2901 in a CoA architecture. Alternatively, the vertical order on carrier wafer 2903 of control wafer 2902 attached to array wafer 2901 can be reversed, configuring architecture 2900 as a CuA architecture.

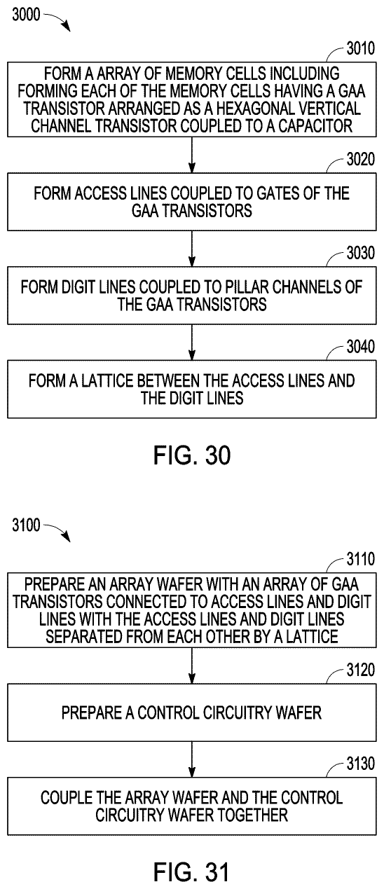

FIG. 30 is a flow diagram of features of an embodiment of an example method 3000 of forming an memory device. At 3010, an array of memory cells is formed, including forming each of the memory cells having a GAA transistor arranged as a hexagonal vertical channel transistor coupled to a capacitor. At 3020, WLs are formed coupled to gates of the GAA transistors. At 3030, BLs are formed coupled to pillar channels of the GAA transistors. The BLs and the WLs are separated from each other in a vertical direction. The vertical direction can be upward or downward depending on the architecture of the memory device being fabricated.

At 3040, a lattice is formed between the WLs and the BLs. The lattice can be formed by forming dielectric regions between and contacting non-dielectric regions and forming each non-dielectric region on and contacting a BL of the BLs. Each non-dielectric region can contain BL contact junctions to pillar channels of a set of the GAA transistors extending from the non-dielectric region. The formation of the memory cells, WLs, BLs, and lattice can be an integrated procedure, which can include varying the sequencing of procedures.

Variations of method 3000 or methods similar to method 3000 can include a number of different embodiments that may be combined depending on the application of such methods and/or the architecture of systems including a memory device for which such methods are implemented. Such methods can include forming each BL at least partially wrapped on sidewalls of the BL contact junctions in the non-dielectric region to which the BL contacts.

Variations of method 3000 or methods similar to method 3000 can include performing a number of procedures to form the BLs and the lattice. The procedures can include forming material for the BLs on a region of epitaxial semiconductor and modifying the material for the BLs into strips of BL material with trenches between the strips of BL material. The trenches can extend below the material for the BLs, where each trench has walls formed by the strips of BL material located on walls of the epitaxial semiconductor. The dielectric regions can be formed in the trenches, with the dielectric regions having a top level below a top of the walls of the epitaxial semiconductor. Additional BL material can be formed on the strips of BL material in the trenches and on the walls of the epitaxial semiconductor in the trenches from the top of the walls of the epitaxial semiconductor to the top level of the dielectric regions. The trenches can be filled with an isolation dielectric between adjacent additional BL material in the trenches. Variations can include the epitaxial semiconductor having epitaxial silicon. Variations can include the material for the BLs being a first metal and the additional BL material being a second metal. The second metal can be a complementary alloy to the first metal such that resistance of a BL of the first and second metals is lower than resistance of the BL of only the first metal.

Variations of method 3000 or methods similar to method 3000 can include forming the WLs as metal WLs to gates of GAA transistors in a first row of the hexagonal vertical channel transistors such that the formed metal WLs are positioned without contacting gates of GAA transistors in a row of the hexagonal vertical channel transistors adjacent the first row.

FIG. 31 is a flow diagram of features of an embodiment of an example method 3100 of forming an memory device. At 3110, an array wafer is prepared with an array of GAA transistors connected to WLs and BLs. The access and BLs are formed separated from each other by a lattice. The lattice can be formed having dielectric regions between and contacting non-dielectric regions. Each non-dielectric region can be formed on and contacting a BL of the BLs and can contain BL contact junctions to pillar channels of a set of the GAA transistors extending from the non-dielectric region.

At 3120, a control circuitry wafer is prepared. At 3130, the array wafer and the control circuitry wafer are coupled together.

Variations of method 3100 or methods similar to method 3100 can include a number of different embodiments that may be combined depending on the application of such methods and/or the architecture of systems including a memory device for which such methods are implemented. Such methods can include forming each BL at least partially wrapped on sidewalls of the BL contact junctions in the non-dielectric region to which the BL contacts. Variations can include forming pillar channels in adjacent rows of the pillar channels, corresponding to a non-dielectric region, that share a BL in a 4F² open BL architecture.

In various embodiments, a memory device can comprise an array of memory cells, WLs, BLs, and a lattice between the WLs and the BLs. Each of the memory cells has a GAA transistor arranged as a hexagonal vertical channel transistor coupled to a capacitor. The WLs are coupled to gates of the GAA transistors, and the BLs are coupled to pillar channels of the GAA transistors. The pillar channels can be structured in a vertical nanowire. The lattice between the WLs and the BLs can have dielectric regions between and contacting non-dielectric regions. The placement and the material selection of the lattice can be tuned to control the mechanical stability of the vertical nanowire structure. Each non-dielectric region can be positioned on and contacting a BL of the BLs and can contain BL contact junctions to the pillar channels of a set of the GAA transistors extending from the non-dielectric region.

Variations of such a memory device and its features, as taught herein, can include a number of different embodiments and features that can be combined depending on the application of such memory devices, the format of such memory devices, and/or the architecture in which such memory devices are implemented. Variations of such memory devices can include each BL at least partially wrapping sidewalls of the BL contact junctions in the non-dielectric region to which the BL contacts. Variations can include each of the BLs having a central BL contacting a pair of side BLs, with one side BL of the pair on an opposite side of the central BL from the other side BL of the pair, the pair of side BLs extending above and below the central digit line

Variations of such a memory device and its features can include each BL having a center aligned between adjacent pillar channels contacting the non-dielectric region to which the BL contacts. Variations can include pillar channels in adjacent rows of pillar channels, corresponding to a non-dielectric region, coupled to a common BL. A given WL of the WLs can have a center aligned to active areas of the GAA transistors to which the given WL is coupled.

Variations of such a memory device and its features can include the array of memory cells of the memory device having a 4F² cell configuration. Variations can include the memory device having control logic and sensing circuitry above the array. The control logic and sensing circuitry and the array of memory cells can be arranged in a wafer-to-wafer interconnect architecture.

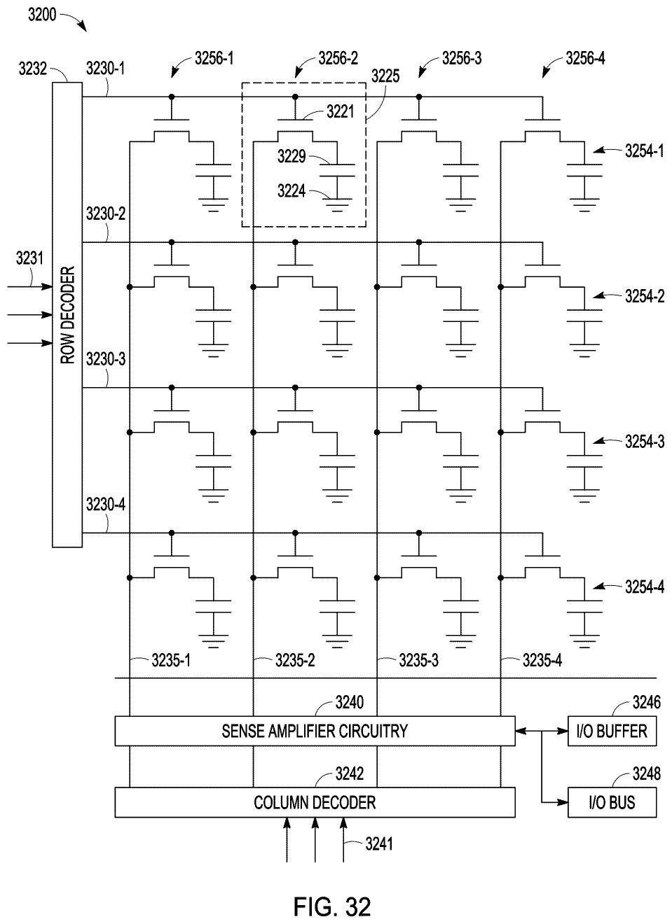

FIG. 32 is a schematic of an electrical arrangement of components of an embodiment of an example DRAM device 3200 that can include an physical architecture having an array of memory cells arranged as hexagonal cells, with each of the memory cells having a GAA transistor coupled to a capacitor. The memory cells can be coupled to BLs and WLs, where WLs can be structured contacting gates of GAA transistors of memory cells to which a given WL is coupled. A lattice can be positioned between the WLs and the BLs, where the lattice has dielectric regions between and contacting non-dielectric regions, with each non-dielectric region on and contacting a BL and containing BL contact junctions to the pillar channels of a set of the GAA transistors extending from the non-dielectric region. The array of memory cells can be structured in an arrangement associated herein with respect to FIGS. 1-31. DRAM device 3200 can include an array of memory cells 3225 (only one being labeled in FIG. 32 for ease of presentation) arranged in rows 3254-1, 3254-2, 3254-3, and 3254-4 and columns 3256-1, 3256-2, 3256-3, and 3256-4. The physical orientation of the rows and columns is not limited to the orientation shown in FIG. 32. Further, while only four rows 3254-1, 3254-2, 3254-3, and 3254-4 and four columns 3256-1, 3256-2, 3256-3, and 3256-4 of four memory cells are illustrated, DRAM devices, like DRAM device 3200, can have significantly more memory cells 3225 (for example, tens, hundreds, or thousands of memory cells) per row or per column.

In this example, each memory cell 3225 can include a single transistor 3221 and a single capacitor 3229, which is commonly referred to as a 1T1C (one-transistor—one capacitor cell). One plate of capacitor 3229, which can be termed the “node plate,” is connected to the drain terminal of transistor 3221, whereas the other plate of the capacitor 3229 is connected to ground 3224 or other reference node. Each capacitor 3229 of memory cell 3225 within the array of 1T1C memory cells typically serves to store one bit of data, and the respective transistor 3221 serves as an access device to write to or read from storage capacitor 3229. Each transistor 3221 can be realized by a GAA nanowire transistor, as discussed with respect to FIGS. 1-31.

The transistor gate terminals within each row of rows 3254-1, 3254-2, 3254-3, and 3254-4 can be portions of respective WLs 3230-1, 3230-2, 3230-3, and 3230-4, and the transistor source terminals within each of columns 3256-1, 3256-2, 3256-3, and 3256-4 can be electrically connected to respective BLs 3235-1, 3235-2, 3235-3, and 3235-4. A row decoder 3232 can selectively drive the individual WLs 3230-1, 3230-2, 3230-3, and 3230-4, responsive to row address signals 3231 input to row decoder 3232. Driving a given WL at a high voltage causes the access transistors within the respective row to conduct, thereby connecting the storage capacitors within the row to the respective BLs, such that charge can be transferred between the BLs and the storage capacitors for read or write operations. Both read and write operations can be performed via SA circuitry 3240, which can transfer bit values between memory cells 3225 of the selected row of the rows 3254-1, 3254-2, 3254-3, and 3254-4 and input/output buffers 3246 (for write/read operations) or external input/output data buses 3248.

A column decoder 3242 responsive to column address signals 3241 can select which of the memory cells 3225 within the selected row is read out or written to. Alternatively, for read operations, the storage capacitors 3229 within the selected row can be read out simultaneously and latched, and the column decoder 3242 can then select which latch bits to connect to the output data bus 3248. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DRAM device 3200 can be implemented as an IC within a package that includes pins for receiving supply voltages (for example, to provide the source and gate voltages for the transistors 3221) and signals (including data, address, and control signals). FIG. 32 depicts DRAM device 3200 in simplified form to illustrate basic structural components relative to electrical interactions, omitting many details of the memory cells 3225 and associated WLs 3230-1, 3230-2, 3230-3, and 3230-4 and BLs 3235-1, 3235-2, 3235-3, and 3235-4 as well as the peripheral circuitry. For example, in addition to the row decoder 3232, column decoder 3242, SA circuitry 3240, and buffers 3246, DRAM device 3200 can include further peripheral circuitry, such as a memory control unit that controls the memory operations based on control signals (provided, for example, by an external processor), additional input/output circuitry, or other features associated with a memory device. Details of such peripheral circuitry are generally known to those of ordinary skill in the art and not further discussed herein. The peripheral circuitry can be located above the array of memory cells 3225 in a CoA architecture using a wafer-to-wafer interconnect architecture. Alternatively, the peripheral circuitry can be located under the array of memory cells 3225 in a CuA architecture. Alternatively, the peripheral circuitry can be located in a region of the IC of the memory device adjacent an array region having the array of memory cells 3225.

In two-dimensional (2D) DRAM arrays, the rows 3254-1, 3254-2, 3254-3, and 3254-4 and columns 3256-1, 3256-2, 3256-3, and 3256-4 of memory cells 3225 can be arranged along a single horizontal plane (i.e., a plane parallel to the layers) of the semiconductor substrate, for example, in a rectangular lattice with WLs 3230-1, 3230-2, 3230-3, and 3230-4 in one plane and BLs 3235-1, 3235-2, 3235-3, and 3235-4 in another plane. In 3D DRAM arrays, the memory cells 3225 can be arranged in a 3D lattice with a set of memory cells and associated WLs and BLs at a level above another set of memory cells and their associated WLs and BLs.

Memory devices having identical or similar features to example DRAM device 3200 and the structures associated with FIGS. 1-32 can be implemented in a variety of electronic devices. Electronic devices, such as mobile electronic devices (for example, smart phones, tablets, and other similar communication-related devices), electronic devices for use in automotive applications (for example, automotive sensors, control units, driver-assistance systems, passenger safety systems, comfort systems, or other similar systems), and internet-connected appliances or devices (for example, internet-of-things (IoT) devices, or other network-related devices), have varying storage needs depending on, among other things, the type of electronic device, use environment, performance expectations, or other criteria.

Such electronic devices can be broken down into several main components: a processor (for example, a central processing unit (CPU) or other main processor); memory (for example, one or more volatile or nonvolatile RAM memory device, such as DRAM, mobile or low-power double-data-rate synchronous DRAM (DDR SDRAM), or other similar memory devices); and a storage device (for example, non-volatile memory (NVM) device, such as flash memory, ROM, a solid-state drive (SSD), a MultiMediaCard (MMC), other memory card structure or assembly, or other similar storage devices). In certain examples, electronic devices can include a user interface (for example, a display, touch-screen, keyboard, one or more buttons, or other similar interfacing structure), a graphics processing unit (GPU), a power management circuit, a baseband processor, one or more transceiver circuits, or other similar device. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

The following examples are example embodiments of devices and methods, in accordance with the teachings herein.

An example memory device 1 can comprise array of memory cells, with each of the memory cells having a GAA transistor arranged as a hexagonal vertical channel transistor coupled to a capacitor; WLs coupled to gates of the GAA transistors; BLs coupled to pillar channels of the GAA transistors; and a lattice between the WLs and the BLs, the lattice having dielectric regions between and contacting non-dielectric regions, each non-dielectric region on and contacting a BL of the BLs and containing BL contact junctions to the pillar channels of a set of the GAA transistors extending from the non-dielectric region.

An example memory device 2 can include features of example memory device 1 and can include each BL at least partially wrapping sidewalls of the BL contact junctions in the non-dielectric region to which the BL contacts.

An example memory device 3 can include features of any of the preceding example memory devices and can include each BL having a center aligned between adjacent pillar channels contacting the non-dielectric region to which the BL contacts.

An example memory device 4 can include features of any of the preceding example memory devices and can include pillar channels in adjacent rows of pillar channels, corresponding to a non-dielectric region, coupled to a common BL.

An example memory device 5 can include features of any of the preceding example memory devices and can include a given WL of the WLs having a center aligned to active areas of the GAA transistors to which the given WL is coupled.

An example memory device 6 can include features of any of the preceding example memory devices and can include each of the digit lines having a central digit line contacting a pair of side digit lines, with one side digit line of the pair on an opposite side of the central digit line from the other side digit line of the pair, the pair of side digit lines extending above and below the central digit line.

An example memory device 7 can include features of any of the preceding example memory devices and can include the array of memory cells having a 4F² cell configuration.

An example memory device 8 can include features of any of the preceding example memory devices and can include control logic and sensing circuitry above the array.

An example memory device 9 can include features of example memory device 8 and any of the preceding example memory devices and can include the control logic and sensing circuitry and the array of memory cells being arranged in a wafer-to-wafer interconnect architecture.

An example memory device 10 can include features of any of the preceding example memory devices and can include the pillar channels being structured in a vertical nanowire.

In an example memory device 11, any of the memory devices of example memory devices 1 to 10 may include memory devices incorporated into an electronic apparatus further comprising a host processor and a communication bus extending between the host processor and the memory device.

In an example memory device 12, any of the memory devices of example memory devices 1 to 11 may be modified to include any structure presented in another of example memory device 1 to 11.

In an example memory device 13, any apparatus associated with the memory devices of example memory devices 1 to 12 may further include a machine-readable storage device configured to store instructions as a physical state, wherein the instructions may be used to perform one or more operations of the apparatus.

In an example memory device 14, any of the memory devices of example memory devices 1 to 13 may be formed in accordance with any of the below example methods 1 to 18 of forming a memory device.

An example method 1 of forming a memory device can comprise forming an array of memory cells including forming each of the memory cells having a GAA transistor arranged as a hexagonal vertical channel transistor coupled to a capacitor; forming WLs coupled to gates of the GAA transistors; forming BLs coupled to pillar channels of the GAA transistors, with the BLs and the WLs separated from each other in a vertical direction; and forming a lattice between the WLs and the BLs, including forming dielectric regions between and contacting non-dielectric regions and forming each non-dielectric region on and contacting a BL of the BLs and containing BL contact junctions to pillar channels of a set of the GAA transistors extending from the non-dielectric region.

An example method 2 of forming a memory device can include features of example method 1 of forming a memory device and can include forming each BL at least partially wrapped on sidewalls of the BL contact junctions in the non-dielectric region to which the BL contacts.

An example method 3 of forming a memory device can include features of example method 2 of forming a memory device and any of the preceding example methods of forming a memory device and can include forming the BLs and the lattice to include: forming material for the BLs on a region of epitaxial semiconductor; modifying the material for the BLs into strips of BL material with trenches between the strips of BL material, the trenches extending below the material for the BLs, with each trench having walls formed by the strips of BL material located on walls of the epitaxial semiconductor; forming the dielectric regions in the trenches having a top level below a top of the walls of the epitaxial semiconductor; forming additional BL material on the strips of BL material in the trenches and on the walls of the epitaxial semiconductor in the trenches from the top of the walls of the epitaxial semiconductor to the top level of the dielectric regions; and filling the trenches between adjacent additional BL material in the trenches with an isolation dielectric.

An example method 4 of forming a memory device can include features of example method 3 and any of the preceding example methods of forming a memory device and can include the epitaxial semiconductor to include epitaxial silicon.

An example method 5 of forming a memory device can include features of example method 3 and any of the preceding example methods of forming a memory device and can include the material for the BLs being a first metal and the additional BL material is a second metal.

An example method 6 of forming a memory device can include features of example method 5 of forming a memory device and any of the preceding example methods of forming a memory device and can include the second metal being a complementary alloy to the first metal such that resistance of a BL of the first and second metals is lower than resistance of the BL of only the first metal.

An example method 7 of forming a memory device can include features of example method 6 of forming a memory array and any of the preceding example methods of forming a memory device and can include forming the WLs to include forming metal WLs to gates of GAA transistors in a first row of the hexagonal vertical channel transistors such that the formed metal WLs are positioned without contacting gates of GAA transistors in a row of the hexagonal vertical channel transistors adjacent the first row.

In an example method 8 of forming a memory device, any of the example methods 1 to 7 of forming a memory device may be performed in forming an electronic apparatus further comprising a host processor and a communication bus extending between the host processor and the memory device.

In an example method 9 of forming a memory device, any of the example methods 1 to 8 of forming a memory device may be modified to include operations set forth in any other of example methods 1 to 8 of forming a memory device.

In an example method 10 of forming a memory device, any of the example methods 1 to 9 of forming a memory device may be implemented at least in part through use of instructions stored as a physical state in one or more machine-readable storage devices.

An example method 11 of forming a memory device can include features of any of the preceding example methods 1 to 10 of forming a memory device and can include forming features associated with any features of example memory devices 1 to 14.

An example method 12 of forming a memory device can comprise preparing an array wafer with an array of GAA transistors connected to WLs and BLs, with the WLs and the BLs separated from each other by a lattice, the lattice including dielectric regions between and contacting non-dielectric regions, with each non-dielectric region on and contacting a BL of the BLs and containing BL contact junctions to pillar channels of a set of the GAA transistors extending from the non-dielectric region; preparing a control circuitry wafer; and coupling the array wafer and the control circuitry wafer together.

An example method 13 of forming a memory device can include features of example method 12 of forming a memory device and can include forming each BL at least partially wrapped on sidewalls of the BL contact junctions in the non-dielectric region to which the BL contacts.

An example method 14 of forming a memory device can include features of any of the preceding example methods 12-13 of forming a memory device and can include forming pillar channels in adjacent rows of the pillar channels, corresponding to a non-dielectric region, sharing a BL in a 4F² open BL architecture.

In an example method 15 of forming a memory device, any of the example methods 12 to 14 of forming a memory device may be performed in forming an electronic apparatus further comprising a host processor and a communication bus extending between the host processor and the memory device.

In an example method 16 of forming a memory device, any of the example methods 12 to 15 of forming a memory device may be modified to include operations set forth in any other of example methods 12 to 15 of forming a memory device.

In an example method 17 of forming a memory device, any of the example methods 12 to 16 of forming a memory device may be implemented at least in part through use of instructions stored as a physical state in one or more machine-readable storage devices.

An example method 18 of forming a memory device can include features of any of the preceding example methods 12 to 17 of forming a memory device and can include forming features associated with any features of example memory devices 1 to 14.

An example machine-readable storage device storing instructions, which instructions when executed by one or more processors, cause a machine to perform operations, can comprise instructions to perform functions associated with any features of example memory devices 1 to 14 or perform methods associated with any features of example methods 1 to 18 of forming a memory device.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells, with each of the memory cells having a gate-all-around (GAA) transistor arranged as a hexagonal vertical channel transistor coupled to a capacitor;
access lines coupled to gates of the GAA transistors;
digit lines coupled to pillar channels of the GAA transistors; and
a lattice between the access lines and the digit lines, the lattice having dielectric regions between and contacting non-dielectric regions, each non-dielectric region on and contacting a digit line of the digit lines and containing digit contact junctions to the pillar channels of a set of the GAA transistors extending from the non-dielectric region.

2. The memory device of claim 1, wherein each digit line at least partially wraps sidewalls of the digit contact junctions in the non-dielectric region to which the digit line contacts.

3. The memory device of claim 1, wherein each digit line has a center aligned between adjacent pillar channels contacting the non-dielectric region to which the digit line contacts.

4. The memory device of claim 1, wherein pillar channels in adjacent rows of pillar channels, corresponding to a non-dielectric region, are coupled to a common digit line.

5. The memory device of claim 1, wherein a given access line of the access lines has a center aligned to active areas of the GAA transistors to which the given access line is coupled.

6. The memory device of claim 1, wherein each of the digit lines has a central digit line contacting a pair of side digit lines, with one side digit line of the pair on an opposite side of the central digit line from the other side digit line of the pair, the pair of side digit lines extending above and below the central digit line.

7. The memory device of claim 1, wherein the array of memory cells has a 4F² cell configuration.

8. The memory device of claim 1, wherein the memory device includes control logic and sensing circuitry above the array.

9. The memory device of claim 8, wherein the control logic and sensing circuitry and the array of memory cells are arranged in a wafer-to-wafer interconnect architecture.

10. The memory device of claim 1, wherein the pillar channels are structured in a vertical nanowire.

11. A method of forming an memory device, the method comprising:
forming an array of memory cells including forming each of the memory cells having a gate-all-around (GAA) transistor arranged as a hexagonal vertical channel transistor coupled to a capacitor;
forming access lines coupled to gates of the GAA transistors;
forming digit lines coupled to pillar channels of the GAA transistors, with the digit lines and the access lines separated from each other in a vertical direction; and
forming a lattice between the access lines and the digit lines, including forming dielectric regions between and contacting non-dielectric regions and forming each non-dielectric region on and contacting a digit line of the digit lines and containing digit contact junctions to pillar channels of a set of the GAA transistors extending from the non-dielectric region.

12. The method of claim 11, wherein the method includes forming each digit line at least partially wrapped on sidewalls of the digit contact junctions in the non-dielectric region to which the digit line contacts.

13. The method of claim 11, wherein forming the digit lines and the lattice includes:
forming material for the digit lines on a region of epitaxial semiconductor;
modifying the material for the digit lines into strips of digit line material with trenches between the strips of digit line material, the trenches extending below the material for the digit lines, with each trench having walls formed by the strips of digit line material located on walls of the epitaxial semiconductor;
forming the dielectric regions in the trenches having a top level below a top of the walls of the epitaxial semiconductor;
forming additional digit line material on the strips of digit line material in the trenches and on the walls of the epitaxial semiconductor in the trenches from the top of the walls of the epitaxial semiconductor to the top level of the dielectric regions; and
filling the trenches between adjacent additional digit line material in the trenches with an isolation dielectric.

14. The method of claim 13, wherein the epitaxial semiconductor includes epitaxial silicon.

15. The method of claim 13, wherein the material for the digit lines is a first metal and the additional digit line material is a second metal.

16. The method of claim 15, wherein the second metal is a complementary alloy to the first metal such that resistance of a digit line of the first and second metals is lower than resistance of the digit line of only the first metal.

17. The method of claim 16, wherein forming the access lines includes forming metal access lines to gates of GAA transistors in a first row of the hexagonal vertical channel transistors such that the formed metal access lines are positioned without contacting gates of GAA transistors in a row of the hexagonal vertical channel transistors adjacent the first row.

18. A method of forming a memory device, the method comprising:
preparing an array wafer with an array of gate-all-around (GAA) transistors connected to access lines and digit lines, with the access lines and the digit lines separated from each other by a lattice, the lattice including dielectric regions between and contacting non-dielectric regions, with each non-dielectric region on and contacting a digit line of the digit lines and containing digit contact junctions to pillar channels of a set of the GAA transistors extending from the non-dielectric region;
preparing a control circuitry wafer; and
coupling the array wafer and the control circuitry wafer together.

19. The method of claim 18, wherein the method includes forming each digit line at least partially wrapped on sidewalls of the digit contact junctions in the non-dielectric region to which the digit line contacts.

20. The method of claim 18, wherein the method includes forming pillar channels in adjacent rows of the pillar channels, corresponding to a non-dielectric region, sharing a digit line in a 4F² open digit line architecture.
